(19) United States
(12) Patent Application Publication
(10) Pub. No.: US 2025/0251241 A1
(43) Pub. Date: Aug. 7, 2025

(54) CONTROL CIRCUIT OF A MEMS GYROSCOPE, MEMS GYROSCOPE AND CONTROL METHOD

(71) Applicant: STMICROELECTRONICS S.r.l., Agrate Brianza (IT)

(72) Inventor: Angelo GRANATA, Siracusa (IT)

(73) Assignee: STMICROELECTRONICS S.r.l., Agrate Brianza (IT)

(21) Appl. No.: 19/186,210

(22) Filed: Apr. 22, 2025

Related U.S. Application Data
(63) Continuation of application No. 17/899,478, filed on Aug. 30, 2022, now Pat. No. 12,305,986.

(30) Foreign Application Priority Data
Sep. 27, 2021 (IT) 102021000024644

(51) Int. Cl. G01C 19/5712; G01C 19/5776; H03M 3/00

(52) U.S. Cl. CPC G01C 19/5712; G01C 19/5776; H03M 3/344; H03M 3/40

(57) ABSTRACT

The control circuit for a MEMS gyroscope is configured to receive a measurement signal which has a quadrature component and a sensing component. The control circuit has: an input stage which acquires an input signal, generating an acquisition signal, where the input signal is a function of the measurement signal and of a quadrature cancellation signal; a processing stage which extracts a first component of the acquisition signal, indicative of the sensing component of the measurement signal and having a sensing frequency band; and a quadrature correction stage which extracts a second component of the acquisition signal, indicative of the quadrature component of the measurement signal, and generates the quadrature cancellation signal from a reference signal. The quadrature cancellation signal is a signal modulated as a function of the second component of the acquisition signal, at an update frequency which is outside the sensing frequency band.

### BACKGROUND

### Technical Field

The present disclosure relates to a control circuit of a MEMS gyroscope, to a MEMS gyroscope and to a control method.

### Description of the Related Art

A gyroscope made using MEMS (“Micro Electro-Mechanical Systems”) technology is formed in one or more dice of semiconductor material, for example silicon, wherein an oscillating system, a driving circuit and a sensing circuit, mutually coupled, are formed.

The oscillating system is formed by one or more movable masses suspended on a substrate and free to oscillate with respect to the substrate with one or more degrees of freedom. The oscillating system further comprises a driving structure, coupled to the driving circuit and configured to cause an oscillation of the one or more movable masses along a driving direction, and a sensing structure, coupled to the sensing circuit and configured to sense a movement of the one or more movable masses along a sensing direction perpendicular to the driving direction.

In some MEMS gyroscopes, driving and sensing may be based on different operating principles, e.g., electromagnetic, piezoelectric or capacitive.

When the MEMS gyroscope rotates with an angular velocity about a rotation axis, a movable mass that oscillates with a linear velocity along a direction perpendicular to the rotation axis is subject to a Coriolis force directed along a direction perpendicular to the rotation axis and to the direction of the linear velocity.

In use, the driving circuit provides a driving signal, for example a voltage in case of capacitive driving, to the driving structure, causing an oscillation of the oscillating structure along the driving direction.

The sensing structure senses a movement of the oscillating system along the sensing direction and provides a corresponding sensing signal to the sensing circuit.

In some MEMS gyroscopes, due to variability and imperfections associated with the manufacturing process of the MEMS gyroscope, the driving signal may generate a spurious movement of the one or more movable masses along the sensing direction, even in the absence of a rotation of the MEMS gyroscope. The spurious movement is sensed by the sensing structure, thus generating a spurious signal, known as a quadrature error, which adds to the sensing signal originating from the rotation of the MEMS gyroscope.

This reduces the sensitivity of the MEMS gyroscope.

In order to reduce the contribution of the quadrature error on the sensing signal, a sensing circuit may comprise a trimming circuit which generates a correction signal configured to cancel the spurious quadrature signal. However, the correction signal value is set during an initial calibration step of the MEMS gyroscope. As a result, this approach does not allow any variations in the spurious quadrature signal to be corrected while using the MEMS gyroscope.

The trimming circuit may be recalibrated multiple times during the life cycle of the MEMS gyroscope. However, this recalibration introduces noise into the MEMS gyroscope output signal, thereby compromising the sensing performances thereof.

### BRIEF SUMMARY

The technical solutions of the present disclosure overcome the disadvantages of the prior art.

According to the present disclosure a control circuit of a MEMS gyroscope, a MEMS gyroscope and a control method are therefore provided.

### BRIEF DESCRIPTION OF THE SEVERAL VIEWS OF THE DRAWINGS

For a better understanding of the present disclosure, some embodiments thereof are now described, purely by way of non-limiting example, with reference to the attached drawings, wherein:

FIG. 1 shows a block diagram of the present MEMS gyroscope, according to an embodiment;

FIG. 2 shows a detailed block diagram of the MEMS gyroscope of FIG. 1;

FIG. 3 shows a circuit diagram of a portion of the MEMS gyroscope of FIG. 2;

FIG. 4 shows a plot of a trend over time of waveforms of the MEMS gyroscope of FIG. 2; and

FIG. 5 shows a block diagram of the present MEMS gyroscope, according to a different embodiment.

### DETAILED DESCRIPTION

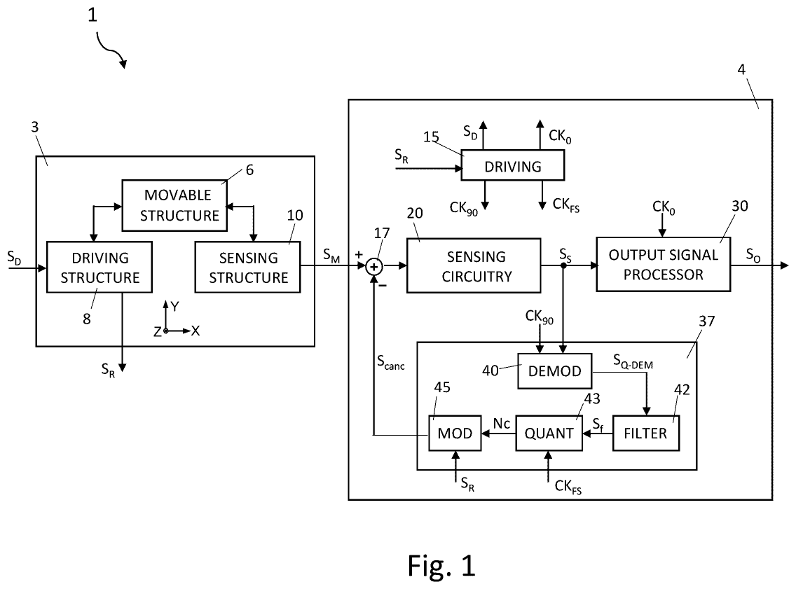

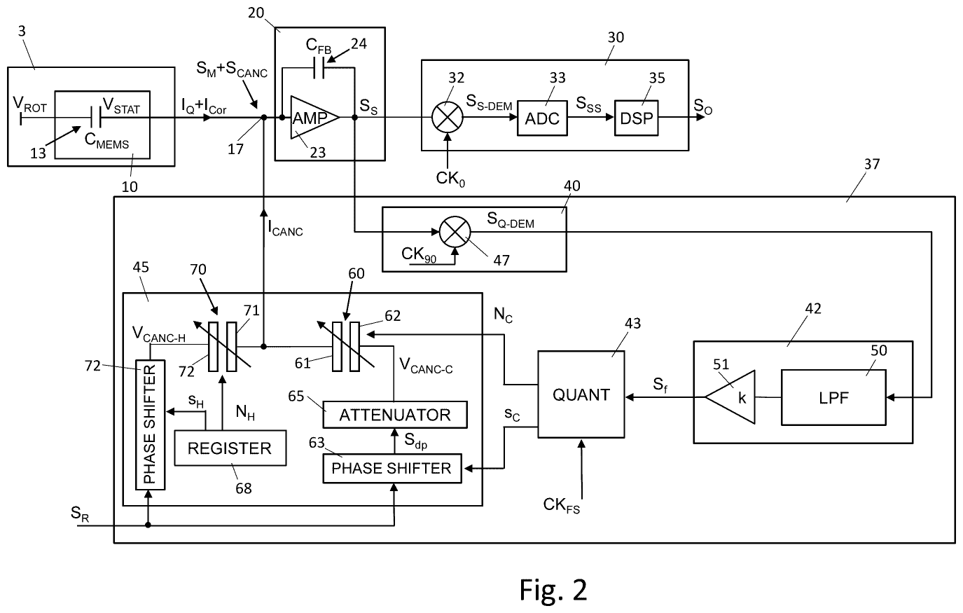

FIGS. 1 and 2 show a MEMS gyroscope 1 comprising an oscillating system 3 and a control circuit 4, which are operatively coupled.

The oscillating system 3 and the control circuit 4 may be formed in a single die of semiconductor material, eg., silicon, or in separate dice.

The oscillating system 3 is made using MEMS technology and comprises a movable and/or deformable structure, hereinafter referred to as movable structure 6, having a resonance frequency fᵣ, a driving structure 8 and a sensing structure 10, mutually coupled.

The driving structure 8 is configured to receive a driving signal Sp from the control circuit 4 and cause a movement, for example, an oscillation, of the movable structure 6 along a driving direction, using an actuation principle, e.g., of electromagnetic, piezoelectric or electrostatic type.

For example, considering a Cartesian reference system XYZ comprising a first axis X, a second axis Y and a third axis Z, the driving direction may be parallel to the first axis X.

Furthermore, in this embodiment, the driving structure 8 generates a position signal SR, indicative of a movement of the movable structure 6 along the driving direction, and provides the position signal S_{R} to the control circuit 4.

For example, if the driving signal S_{D} causes an oscillation of the movable mass 6 at the resonance frequency fᵣ, then the position signal S_{R} is a periodic signal, for example, sinusoidal, having the resonance frequency fᵣ and whose amplitude is a function of the position variation of the movable structure 6.

The position signal S_{R} may be generated using a sensing principle of capacitive, piezoelectric, piezoresistive or electromagnetic type, according to the specific application.

The sensing structure 10 is configured to sense a movement of the movable structure 6 along a sensing direction, for example perpendicular to the driving direction, for example parallel to the second axis Y, and generate a corresponding measurement signal S_{M}, which is provided to the control circuit 4.

In this embodiment, as shown in FIG. 2, the sensing structure 10 operates according to a capacitive sensing principle and is formed by a sensing capacitor 13 having, at rest, a capacitance C_{MEMS}.

However, the sensing structure 10 may generate the measurement signal S_{M} using a different sensing principle, e.g., of electromagnetic or piezoelectric type.

Here, the sensing capacitor 13 is schematically represented by a parallel plate capacitor; however, the sensing capacitor 13 may be of different type, e.g., an interdigitated capacitor.

The sensing capacitor 13 has a first terminal at a rotor voltage V_{ROT}, which may be applied by the control circuit 4, and a second terminal at a stator voltage V_{STAT} forming the measurement signal S_{M}.

For example, the rotor voltage V_{ROT} is a DC voltage that allows to set a desired initial value of the potential difference of the sensing capacitor 13, useful in specific applications, eg., to tune the sensing sensitivity of the sensing capacitor 13.

The control circuit 4 provides the driving signal S_{D} to the oscillating system 3 and receives the measurement signal S_{M} from the oscillating system 3.

In this embodiment, the control circuit 4 also receives the position signal S_{R} from the oscillating system 3.

Furthermore, the control circuit 4 generates, from the measurement signal S_{M}, an output signal S₀, of digital type, having an output data rate (or frequency) f₀ for example comprised between 10 Hz and 10 KHz.

In detail, the control circuit 4 comprises a driving module 15 which receives the position signal S_{R}.

The driving module 15 generates the driving signal S_{D}, having a driving frequency f_{D}, e.g., a voltage having sinusoidal behavior over time, a sequence of pulses or a square wave, and provides the driving signal S_{D} to the driving structure 8, for the actuation of the movable structure 6.

The driving frequency f_{D} may be chosen, at the design step, as a function of the electrical and/or mechanical characteristics of the oscillating system 3, eg., as a function of the resonance frequency fᵣ of the movable structure 6, and of the control circuit 4.

The driving module 15 may adjust the driving signal S_{D}, eg., it may adjust the amplitude thereof in case of sinusoidal signal or the duty cycle in case of square wave, so that the movement of the movable structure 6 follows a desired profile over time, eg., has a desired oscillation amplitude, which may be chosen at the design step.

In this regard, the driving module 15 may adjust the driving signal S_{D} as a function of the position signal S_{R}, for example by comparing the position signal S_{R} with one or more values indicative of the desired movement profile of the movable structure 6.

A gain with reference to FIG. 1, the driving module 15 also generates an in-phase clock signal CK₀ and an out-of-phase clock signal CK₉₀, for example two periodic square wave signals, which have the driving frequency f_{D} and are mutually phase-shifted, for example, phase-shifted by 90°.

The in-phase clock signal CK₀ and the out-of-phase clock signal CK₉₀ are, as a first approximation, except for latencies introduced by the driving module 15, in quadrature and, respectively, in-phase with respect to the position signal S_{R}.

In detail, the rising (or falling) edges of the in-phase clock signal CK₀ are synchronized with the peaks (or valleys) of the position signal S_{R}.

The rising and falling edges of the out-of-phase clock signal CK₉₀ are synchronized with the zero crossings of the position signal S_{R}.

Furthermore, since, as a first approximation, the position signal S_{R} is at the driving frequency f_{D} and is phase-shifted by 90° with respect to the driving signal S_{D}, the in-phase clock signal CK₀ and the out-of-phase clock signal CK₉₀ are in-phase and, respectively, in quadrature, with respect to the driving signal SD.

The driving module 15 also generates a correction clock signal CK_{FS}, eg., a periodic square wave signal, having a frequency f_{F5} outside a frequency band of interest BW of the MEMS gyroscope 1, for example greater than the output frequency f₀ of the output signal S₀, as described in detail hereinbelow.

Furthermore, the frequency f_{F5} of the correction clock signal CK_{FS} may be equal to or different from the driving frequency f_{D}, eg., greater than the driving frequency f_{D}, for example equal to double the driving frequency f_{D}.

According to an embodiment, the rising (or falling) edges of the correction clock signal CK_{F5} are synchronized with the zero crossings of the position signal S_{R}. This is useful when using the MEMS gyroscope 1, as described herein.

In some embodiments, as also discussed herein, the control circuit 4 uses the position signal S_{R} as a reference signal.

The control circuit 4 has an input adder node 17 receiving the measurement signal S_{M} and a cancellation signal S_{CANC}, and a sensing circuitry 20, coupled to the output of the input adder node 17 and configured to provide a sensing signal Ss.

In operation, the sensing circuitry 20 receives a combined signal S_{M}+S_{CANC} given by the superimposition of the measurement signal S_{M} and the cancellation signal S_{CANC}.

In some embodiments, as shown in FIG. 2, the sensing circuitry 20 comprises an amplifier 23 and a feedback capacitor 24 having capacitance C_{FB} and coupled between input and output of the amplifier 23.

Furthermore, in some embodiments, the input of the amplifier 23 is directly coupled to the second terminal of the sensing capacitor 13, i.e, to the stator voltage V_{STAT}, through the input adder node 17 and the output of the amplifier 23 provides the sensing signal S_{S}.

The control circuit 4 comprises a signal processing module 30, which receives the sensing signal S_{S} and the in-phase clock signal CK₀ and provides the output signal So.

In detail, the signal processing module 30 comprises a demodulator 32 and an analog-to-digital converter 33.

The demodulator 32 receives the sensing signal S_{S} and the in-phase clock signal CK₀ and provides a demodulated sensing signal S_{S-DEM}.

The demodulated sensing signal S_{S-DEM} is formed by a component of the sensing signal S_{S} which is in quadrature with the position signal S_{R} (and therefore in-phase with the driving signal S_{D}) and indicative of a movement of the movable mass 6 caused by a rotation of the MEMS gyroscope 1.

The demodulated sensing signal S_{S-DEM} comprises the frequency band of interest BW, comprised between a minimum frequency, eg., between 0 Hz and 50 Hz, and a maximum frequency, eg., comprised between 100 Hz and 10 KHz.

The frequency band of interest BW is used to determine the rotation extent of the MEMS gyroscope 1, for example a rotation angular velocity, and may be chosen during the design step as a function of the electrical and mechanical characteristics of the oscillating system 3, for example of the movable structure 6 and of the sensing structure 10, and of the electrical characteristics of the signal processing module 30.

The analog-to-digital converter 33 receives the demodulated sensing signal S_{S-DEM} and discretizes it using a sampling frequency f_{SS}, generating a discretized signal S_{SS}.

The sampling frequency f_{SS} may be chosen at the design step as a function of the frequency band of interest BW, according to the specific application.

The sampling frequency f_{SS} may be lower than or equal to a maximum value that may be chosen as a function of the frequency band of interest BW, for example equal to double the maximum frequency of the frequency band of interest BW.

The analog-to-digital converter 33 may further comprise amplifiers and/or filters configured to condition the demodulated sensing signal S_{S-DEM} before its discretization, according to the specific application.

Furthermore, in this embodiment, the signal processing module 30 also comprises a digital processor 35 configured to perform further processing of the discretized signal S_{SS} such as for example filtering and gain of the discretized signal S_{SS}, generating the output signal So.

Furthermore, the digital processor 35 may be configured to modify the sample rate of the discretized signal S_{SS}. In detail, the output frequency f₀ may be different, for example lower than or equal to the sampling frequency f_{SS} of the discretized signal S_{SS}.

The control circuit 4 further comprises a correction module 37 which operates as a quantization-noise shaper and generates the correction signal S_{canc}, as described hereinbelow.

In some embodiments, the correction module 37 comprises a quadrature demodulator 40, a filtering stage 42, a quantizer 43 and a correction modulator 45, mutually coupled.

In some embodiments, the correction module 37 is a sigma-delta modulator.

The quadrature demodulator 40 comprises a demodulator 47 which receives the sensing signal S_{S} and the out-of-phase clock signal CK₉₀ at input and provides a demodulated quadrature signal S_{Q-DEM}.

The demodulated quadrature signal S_{Q-DEM} is formed by a component of the sensing signal S_{S} which is in-phase with the position signal S_{R}, and therefore in quadrature with respect to the driving signal S_{D}.

The filtering stage 42 has a cut-off frequency, receives the demodulated quadrature signal S_{Q-DEM} and generates a filtered signal S_{f}.

The cut-off frequency of the filtering stage 42 may be chosen at the design step, according to the specific application.

For example, the cut-off frequency of the filtering stage 42 is chosen as a function of the frequency band of interest BW and/or of the sampling frequency f_{SS}, e.g., may be equal to the maximum frequency of the frequency band of interest BW.

In some embodiments, the filtering stage 42 comprises a low-pass filter 50, receiving the demodulated quadrature signal S_{Q-DEM}, and an amplifier 51 having a gain k, coupled to an output of the low-pass filter 50 and configured to provide the filtered signal S_{f}.

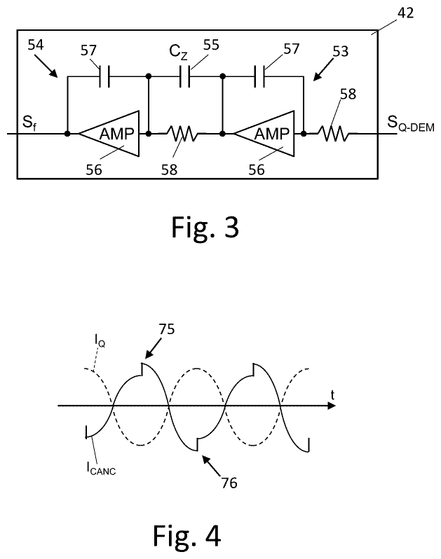

FIG. 3 shows in detail the circuit diagram of an embodiment of the filtering stage 42, here formed by an RC-type active circuit of the second order. For example, the filtering stage 42 comprises two RC filtering stages 53, 54 mutually cascade-coupled through a capacitor 55 of capacitance C_{Z}, where each RC filtering stage comprises a respective amplifier 56, a capacitor 57 and a resistor 58.

However, the filtering stage 42 may be of an order N other than two and may be of different type, for example may be formed by transconductance elements or may be of passive type and formed by a network of inductors and capacitors.

With reference back to FIGS. 1 and 2, the quantizer 43 receives the filtered signal Sf and the correction clock signal CK_{FS}.

The quantizer 43, for example having a single-bit or multibit architecture, eg., of FLASH type or of the Successive Approximation Register (SAR) type, generates a fine capacitance signal N_{C}, discrete, as a function of the value of the filtered signal S_{f}, with a frequency equal to the frequency f_{FS} of the correction clock signal CK_{FS}.

According to an embodiment, the quantizer 43 may be configured to compare the value of the filtered signal S_{f} with a threshold value Vth, at each event, for example a rising or falling edge, of the correction clock signal CK_{FS}.

For example, the threshold value Vth may be equal to zero and if the filtered signal S_{f}, in modulus, is greater than the threshold value Vth, then the quantizer 43 may increase (or decrease) the value of the fine capacitance signal N_{C} by one unit.

For example, the quantizer 43 may generate the fine capacitance signal N_{C} so that the fine capacitance signal N_{C} is equal to the numerical value, eg., in binary format, of the ratio between the filtered signal S_{f} and a conversion reference signal, for example equal to the threshold value Vth.

However, the quantizer 43 may be configured to modify the value of the fine capacitance signal N_{C} in a different manner, for example by using a non-binary coding code, for example, of thermometric type.

Additionally or alternatively, the quantizer 43 may be configured to have a dithering function on the fine capacitance signal N_{C}.

In operation, the quantizer 43 updates the value of the fine capacitance signal N_{C} with a frequency equal to the frequency f_{FS} of the correction clock signal CK_{FS}.

In some embodiments, the quantizer 43 further provides a fine sign signal sc, indicative of the sign of the filtered signal S_{f}, and therefore of the demodulated quadrature signal S_{Q-DEM}. In operation, the fine sign signal s_{C} indicates the phase-shift sign of the quadrature component of the sensing signal S_{S} with respect to the position signal S_{R}, eg., whether the quadrature component of the sensing signal S_{S} is phase-shifted by 0° or by 180° with respect to the position signal S_{R}.

The correction modulator 45 receives the fine capacitance signal N_{C} and the position signal S_{R}, and generates the cancellation signal S_{canc}.

In this embodiment, the correction modulator 45 comprises a first variable capacitor 60, whose capacitance value is controlled by the fine capacitance signal N_{C}. For example, the first variable capacitor 60 may be formed by a plurality of parallel-coupled capacitive modules, each of which may be activated or deactivated as a function of the value indicated by the fine capacitance signal N_{C}.

The correction modulator 45 further comprises a first phase shifter 63, receiving the position signal S_{R} and the fine sign signal s_{C}, and an attenuator 65 coupled to an output of the first phase shifter 63.

The first phase shifter 63 provides a phase-shifted signal S_{dp} to the attenuator 65. The phase-shifted signal S_{dp} is equal to the position signal S_{R} or to the position signal S_{R} with a phase shift, for example, a phase-shift of 180°, as a function of the sign value indicated by the fine sign signal s_{C}.

The attenuator 65 attenuates the phase-shifted signal S_{dp} generating a fine cancellation voltage V_{CANC-C}.

The first variable capacitor 60 has a first terminal 61 coupled to the input adder node 17 and a second terminal 62 coupled to the output of the attenuator 65, i.e., to the fine cancellation voltage V_{CANC-C}.

In this embodiment, the correction modulator 45 further comprises a register 68, a second variable capacitor 70 and a second phase shifter 72.

The register 68 provides the second variable capacitor 70 with a coarse capacitance signal N_{H} that is configured to set the capacitance value of the second variable capacitor 70.

For example, the second variable capacitor 70 may be formed by a plurality of parallel-coupled capacitive modules, each of which may be activated or deactivated as a function of the value indicated by the coarse capacitance signal N_{H}.

The value of the coarse capacitance signal N_{H} may be determined during an initial calibration step of the MEMS gyroscope 1 and/or may be modified in case of subsequent calibration steps of the MEMS gyroscope 1.

The register 68 further provides a coarse sign signal S_{H} to the second phase shifter 72, indicative of an initial sign of the phase-shift between the quadrature component of the sensing signal S_{S} and the position signal S_{R}, measured in the initial calibration step.

The second phase shifter 72 receives the position signal S_{R} and provides a coarse cancellation voltage V_{CANC-H}. The coarse cancellation voltage V_{CANC-H} is equal to the position signal S_{R} or to the position signal S_{R} with a phase shift, for example a phase shift of 180°, as a function of the sign value indicated by the coarse sign signal S_{H}.

The second variable capacitor 70 has a first terminal 71 coupled to the input adder node 17 and a second terminal 72 coupled to the output of the second phase shifter 72, i.e., to the coarse cancellation voltage V_{CANC-H}.

In operation, the driving signal S_{D} causes an oscillation of the driving structure 8 along the driving direction, eg., the first axis X. In the presence of a rotation of the MEMS gyroscope 1 about an axis transverse to the driving direction, eg., about the third axis Z, the movable structure 6 undergoes a displacement along the sensing direction, parallel to the second axis Y in the considered example. The movement of the movable structure 6 modifies the capacitance value C_{MEMS} of the sensing capacitor 13. As a result, the sensing capacitor 13 generates a measurement current I_{Cor}, indicative of the rotation of the MEMS gyroscope 1.

Due to manufacturing imperfections of the oscillating system 3, the driving signal S_{D} may cause a spurious movement of the movable structure 6 along the sensing direction even in the absence of rotations of the MEMS gyroscope 1. The spurious movement may be sensed by the sensing capacitor 13, which therefore also generates a quadrature current I_{Q} which adds to the measurement current I_{Cor}.

The quadrature current I_{Q} is phase-shifted with respect to the measurement current I_{Cor}, for example phase-shifted by 90°, thus introducing a quadrature component in the measurement signal S_{M}.

The correction signal S_{CANC} here comprises a cancellation current I_{CANC} generated by the first and the second variable capacitors 60, 70 from the reference signal, here the position signal S_{R}. In detail, the capacitance of the fine variable capacitor 60 and of the coarse variable capacitor 70 cause the cancellation current I_{CANC} to have an amplitude that is equal, in modulus, to the quadrature current I_{Q}, as shown in the graph of FIG. 4, wherein the quadrature current I_{Q} is indicated by a dashed line.

Furthermore, the first and the second phase shifters 63, 72 cause the cancellation current I_{CANC} to have an opposite sign or direction with respect to the quadrature current I_{Q}, as again shown in FIG. 4.

In operation, the cancellation current I_{CANC} cancels the quadrature current I_{Q}; therefore, the amplifier 23 receives and amplifies, as a first approximation, only the component of the measurement signal S_{M} given by the rotation of the MEMS gyroscope 1.

The fact that the capacitance of the fine variable capacitor 60 is updated, in operation, at the frequency f_{FS} of the correction clock signal CK_{FS}, causes a possible noise introduced by the quantization of the filtered signal S_{f} to be at a frequency which is outside the band of interest BW of the demodulated sensing signal S_{S-DEM} that is used to sense the rotation of the MEMS gyroscope 1.

The frequency f_{FS} of the correction clock signal CK_{FS} may be greater than the maximum frequency of the frequency band of interest BW.

For example, the frequency f_{FS} of the correction clock signal CK_{FS} may be greater than the output frequency f₀ of the output signal S₀.

In operation, the correction module 37, for example the fine variable capacitor 60, allows the correction signal S_{CANC} to be modulated in an adaptive manner, so as to compensate for variations in the quadrature current I_{Q}, when using the MEMS gyroscope 1, without introducing noise in the frequency band of interest BW. The MEMS gyroscope 1 is therefore able to effectively compensate for variations in the quadrature error component of the measurement signal S_{M}, without compromising the sensing sensitivity of a rotation of the MEMS gyroscope 1.

According to an embodiment, as shown for example in FIG. 4, the cancellation current I_{CANC} is updated in update time instants 75, 76, corresponding respectively to peaks and valleys of the cancellation current I_{CANC}.

The peaks and valleys of the cancellation current I_{CANC} correspond to the instants when the coarse cancellation voltage V_{CANC-C} has maximum slope, i.e, when it crosses the zero value. In practice, the correction clock signal CK_{FS} is synchronized with the zero crossings of the position signal S_{R}.

In this manner, the capacitance variation of the first variable capacitor 60 occurs when the voltage across the first variable capacitor 60 has the value zero, thus avoiding the occurrence of peak currents associated with the charging and discharging of the first variable capacitor 60 during the updating of the respective capacitance value, which might compromise the performances of the MEMS gyroscope 1.

For example, if the frequency f_{FS} of the correction clock signal CK_{FS} is equal to double the driving frequency f_{D}, as shown in FIG. 4, the update frequency of the coarse capacitance signal N_{C} and therefore of the cancellation current I_{CANC} may be maximized.

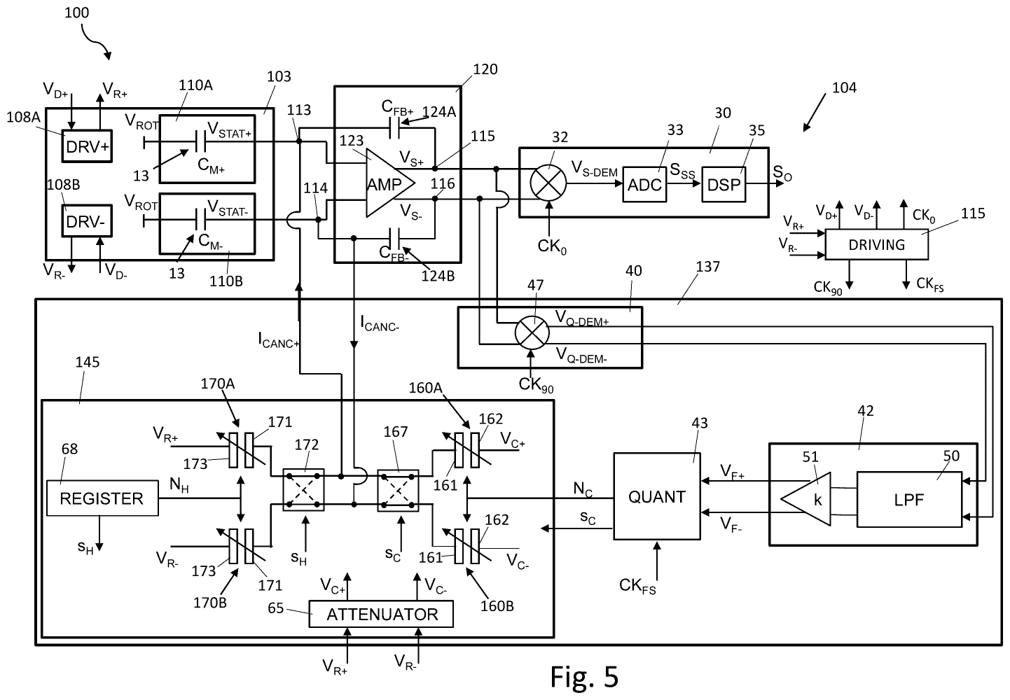

FIG. 5 shows a different embodiment of the present MEMS gyroscope, here indicated by 100. The MEMS gyroscope 100 has a general structure similar to that of the MEMS gyroscope 1; accordingly, elements in common are indicated by the same reference numerals and are not further described.

The MEMS gyroscope 100 has a differential architecture and is formed here again by an oscillating system, here indicated by 103, and comprising a movable structure, not shown here, a first and a second driving structure 108A, 108B, and a first and a second sensing structure 110A, 110B, and by a control circuit, here indicated by 104.

The first and the second sensing structures 110A, 110B are equal to the sensing structure 10 of the MEMS gyroscope 1. In detail, the first sensing structure 110A forms a sensing capacitor 13 having capacitance C_{M+} and whose terminals are at a rotor voltage V_{ROT} and at a positive stator voltage V_{STAT+}, respectively.

The second sensing structure 110B forms a sensing capacitor 13 having capacitance C_{M-} and whose terminals are at the rotor voltage V_{ROT} and at a negative stator voltage V_{STAT-}, respectively.

In practice, the first and the second sensing structures 110A, 110B are configured to sense, in a differential manner, a movement of the movable structure along the sensing direction.

The first and the second driving structures 108A, 108B are each equal to the driving structure 8 of the MEMS gyroscope 1. In this embodiment, the first driving structure 108A receives a driving signal, here a positive driving voltage V_{D+}, and generates a position signal, here a positive position voltage V_{R+}, and the second driving structure 108B receives a driving signal, here a negative driving voltage V_{D-}, and generates a position signal, here a negative position voltage V_{R-}.

In operation, the first and the second driving structures 108A, 108B are configured to drive the movable structure and sense the movement of the movable structure along the driving direction, in a differential manner.

The control circuit 104 comprises a sensing circuitry, here indicated by 120, the signal processing module 30, a driving module, here indicated by 115, and a correction module, here indicated by 137.

The driving module 115 generates the positive driving voltage V_{D+} and the negative driving voltage V_{D-}, mutually phase-shifted by 180°, each having the driving frequency f_{D}.

The driving module 115 receives the positive position voltage V_{R+} and the negative position voltage V_{R-} and generates here again the in-phase clock signal CK₀, the out-of-phase clock signal CK₉₀ and the correction clock signal CK_{FS}.

The in-phase clock signal CK₀ is in quadrature with a difference signal V_{R+}-V_{R-} given by the difference between the positive position voltage V_{R+} and the negative position voltage V_{R-}.

In detail, the rising (or falling) edges of the in-phase clock signal CK₀ are synchronized with the peaks (or valleys) of the difference signal V_{R+}-V_{R-}. The rising (or falling) edges of the out-of-phase clock signal CK₉₀ are synchronized with the zero crossings of the difference signal V_{R+}-V_{R-}.

The sensing circuitry 120 comprises an amplifier 123, of differential type, having two inputs, of which a positive input 113 and a negative input 114, and two outputs, of which a negative output 115 and a positive output 116.

The positive input 113 is coupled to the terminal of the first sensing structure 110A at the positive stator voltage V_{STAT+}, and the negative input 114 is coupled to the terminal of the second sensing structure 110B at the negative stator voltage V_{STAT-},

The sensing circuitry 120 further comprises a first feedback capacitor 124A, having capacitance C_{FB+} and coupled between the positive input 113 and the negative output 115 of the amplifier 123, and a second feedback capacitor 124B, having capacitance C_{FB-} and coupled between the negative input 114 and the positive output 116 of the amplifier 123.

The negative output 115 and the positive output 116 of the amplifier 123 are respectively at a positive sensing voltage V_{S+} and at a negative sensing voltage V_{S-}.

In this embodiment, the signal processing module 30 receives the positive sensing voltage V_{S+} and the negative sensing voltage V_{S-}. The demodulator 32 demodulates the positive sensing voltage V_{S+} and the negative sensing voltage V_{S-} using the in-phase clock signal CK₀ and generates the demodulated sensing signal, herein indicated by V_{S-DEM}.

The analog-to-digital converter 33 and the digital processor 35 generate, from the demodulated sensing signal V_{S-DEM}, the output signal S₀ at the output frequency f₀, as described above for the MEMS gyroscope 1.

The correction module 137 comprises the quadrature demodulator 40 including the demodulator 47, the filtering stage 42 including the filter 50 and the amplifier 51, the quantizer 43 and the correction modulator, here indicated by 145.

The demodulator 47 receives and demodulates the positive sensing voltage V_{S+} and the negative sensing voltage V_{S-} using the out-of-phase clock signal CK₉₀, from which it generates a positive demodulated quadrature voltage V_{Q-DEM+} and a negative demodulated quadrature voltage V_{Q-DEM-}, respectively.

The filtering stage 42 receives the positive demodulated quadrature voltage V_{Q-DEM+} and the negative demodulated quadrature voltage V Q-DEM-, from which it generates a positive filtered voltage V_{f+} and a negative filtered voltage V_{f-}, respectively.

The quantizer 43 receives the positive filtered voltage V_{f+} and the negative filtered voltage V_{f-} and provides the fine capacitance signal N_{C}.

In some embodiments, the value of the fine capacitance signal N_{C} is updated at the frequency f_{FS} of the correction clock signal CK_{FS} and depends on the difference between the positive filtered voltage V_{f+} and the negative filtered voltage V_{f-}, for example with respect to a threshold voltage, which may be determined during the calibration step.

Also here, the quantizer 43 provides the fine sign signal s_{C}, indicative of the sign of the difference between the positive filtered voltage V_{f+} and the negative filtered voltage V_{f-}.

The correction module 145 comprises the attenuator 65, a first and a second fine variable capacitor 160A, 160B, equal to each other, and a first signal switch or deviator 167.

The attenuator 65 receives and attenuates the positive position voltage V_{R+} and the negative position voltage V_{R-}, from which it generates a positive cancellation voltage V_{C+} and a negative cancellation voltage V_{C-}, respectively.

The first and the second fine variable capacitors 160A, 160B receive the fine capacitance signal N_{C}, which controls the capacitance value thereof. For example, the first and the second fine variable capacitors 160A, 160B may each be formed by a plurality of capacitive modules mutually coupled in parallel which may be activated or deactivated as a function of the value indicated by the fine capacitance signal N_{C}.

The first and the second fine variable capacitors 160A, 160B each have a first terminal 161 coupled to a respective input of the first deviator 167, and a second terminal 162 to the positive cancellation voltage V_{C+} and, respectively, to the negative cancellation voltage V_{C-}.

The first deviator 167 is controlled by the fine sign signal sc and has a first output coupled to the positive input 113 of the amplifier 123 and a second output coupled to the negative input 114 of the amplifier 123.

For example, when the fine sign signal sc indicates a negative sign, the first deviator 167 couples (as indicated in FIG. 5 by the dashed lines inside the first deviator 167) the first fine variable capacitor 160A to the negative input 114 of the amplifier 123 and the second fine variable capacitor 160B to the positive input 113 of the amplifier 123.

Conversely, when the fine sign signal s_{C} indicates a positive sign, the first deviator 167 couples (as indicated in FIG. 5 by the solid lines inside the first deviator 167) the first fine variable capacitor 160A to the positive input 113 of the amplifier 123 and the second fine variable capacitor 160B to the negative input 114 of the amplifier 123.

The modulation block 145 further comprises the register 68, which stores the coarse capacitance signal N_{H} and the coarse sign signal S_{H}, a first and a second coarse variable capacitor 170A, 170B, and a second deviator 172.

The first and the second coarse variable capacitors 170A, 170B receive the coarse capacitance signal N_{H}, which controls the capacitance value thereof. For example, the first and the second coarse variable capacitors 170A, 170B may each be formed by a plurality of capacitive modules mutually coupled in parallel which may be activated or deactivated as a function of the value indicated by the coarse capacitance signal N_{H}.

The first and the second coarse variable capacitors 170A, 170B each have a first terminal 171 coupled to a respective input of the second deviator 172, and a second terminal 173 to the positive position voltage V_{R+} and, respectively, to the negative position voltage V_{R-}.

The second deviator 172 is controlled by the coarse sign signal S_{H} and has a first output coupled to the positive input 113 of the amplifier 123 and a second output coupled to the negative input 114 of the amplifier 123.

For example, when the coarse sign signal S_{H} indicates a negative sign, the second deviator 172 couples the first coarse variable capacitor 170A to the negative input 114 of the amplifier 123 and the second coarse variable capacitor 170B to the positive input 113 of the amplifier 123, as indicated in FIG. 5 by the dashed lines inside the second deviator 172.

Conversely, when the coarse sign signal S_{H} indicates a positive sign, the second deviator 172 couples the first coarse variable capacitor 170A to the positive input 113 of the amplifier 123 and the second coarse variable capacitor 170B to the negative input 114 of the amplifier 123, as indicated in FIG. 5 by the solid lines inside the second deviator 172.

In operation, the correction modulator 145 allows a positive cancellation current I_{CANC+} and a negative cancellation current I_{CANC-} to be generated, in a manner similar to what has been discussed above for the correction modulator 45 of the MEMS gyroscope 1. The positive cancellation current I_{CANC+} and the negative cancellation current I_{CANC-} cancel any quadrature component generated by the sensing capacitors 13 of the first and the second sensing structures 110A, 110B.

At the input of the amplifier 123, the quadrature components of the measurement signal S_{M} are thus compensated. The output signal S₀ of the MEMS gyroscope 100 is not affected by the quadrature error and the MEMS gyroscope 100 has a high sensing sensitivity.

Furthermore, in this embodiment, the first and the second deviators 167, 172 allow, in use, the sign of the cancellation signal S_{CANC}, here obtained in a differential manner from the positive cancellation current I_{CANC+} and from the negative cancellation current I_{CANC-}, to be inverted.

Finally, it is clear that modifications and variations may be made to the MEMS gyroscope 1, 100 described and illustrated herein without thereby departing from the scope of the present disclosure, as defined in the attached claims.

The coarse variable capacitor 70 and/or the first and the second coarse variable capacitors 170A, 170B may also be controlled by a respective capacitance signal generated by a respective quantizer.

Alternatively or additionally, the correction modulator 45 may be formed by a single modulation group comprising the fine variable capacitor 60 and the first phase shifter 63. Similarly, the correction modulator 145 may be formed by a single modulation group comprising the first and the second fine variable capacitors 160A, 160B and the first deviator 167.

For example, in the MEMS gyroscope 1 of FIG. 2, the mutual arrangement of the attenuator 65 and the first phase shifter 63 may be inverted.

Furthermore, for example, in the correction modulators 45, 145, the cancellation signals I_{CANC}, I_{CANC+}, I_{CANC-} may be generated directly from the respective position signals S_{R}, V_{R+}, V_{R-}, i.e, without the position signals being subject to attenuation.

The correction modulators 45, 145 may be configured to generate the cancellation signal S_{CANC} in a different manner.

For example, with reference to the modulation block 45 of the MEMS gyroscope 1, the cancellation current I_{CANC} may be obtained by maintaining the fine cancellation voltage V_{CANC-C} constant over time and varying the capacitance of the fine variable capacitor 60 at the driving frequency over time.

For example, the control circuit 4 may comprise an analog-to-digital converter so that the quadrature demodulator 40 and/or the filtering stage 42 may be implemented using a digital architecture, rather than an analog architecture.

For example, the MEMS gyroscope 1, 100 may be of monoaxial, biaxial or triaxial type.

For example, the movable structure 6 may comprise one or more movable masses, according to the specific application of the MEMS gyroscope 1, 100. In case the movable structure 6 comprises a plurality of movable masses, the MEMS gyroscope 1, 100 may comprise a plurality of driving structures, for example one for each movable mass. Alternatively, the MEMS gyroscope 1, 100 may comprise a single driving structure coupled to a movable driving mass and the remaining movable masses may be suitably elastically coupled to the movable driving mass.

Finally, the described embodiments may be combined to form further solutions.

A control circuit (4; 104) for a MEMS gyroscope (1; 100), configured to receive a measurement signal (S_{M}) having a quadrature component (I_{Q}) and a sensing component (I_{Cor}) from the MEMS gyroscope, the control circuit may be summarized as including an input stage (17, 20; 113, 114, 120) configured to acquire an input signal (S_{M}+S_{CANC}) and to generate an acquisition signal (S_{S}; V_{S+}, V_{S-}) in response to the acquisition of the input signal, the input signal being a function of the measurement signal and of a quadrature cancellation signal (S_{CANC}, I_{CANC}; I_{CANC+}, I_{CANC-}); a processing stage (30) configured to extract a first component (S_{S-DEM}; V_{S-DEM}) of the acquisition signal (S_{S}; V_{S+}, V_{S-}), the first component of the acquisition signal being indicative of the sensing component of the measurement signal and having a sensing frequency band; and a quadrature correction stage (37; 137) configured to extract a second component (S_{Q-DEM}; V_{Q-DEM+}, V_{Q-DEM-}) of the acquisition signal (S_{S}; V_{S+}, V_{S-}), the second component of the acquisition signal being indicative of the quadrature component of the measurement signal, and to generate the quadrature cancellation signal (S_{CANC}, I_{CANC}; I_{CANC+}, I_{CANC-}) from a reference signal (S_{R}, V_{CANC-C}; V_{C+}, V_{C-}), wherein the quadrature cancellation signal is a signal modulated as a function of the second component of the acquisition signal, at an update frequency (f_{FS}) which is outside the sensing frequency band.

The quadrature correction stage may be a sigma-delta modulator.

The quadrature correction stage (37; 137) may include a filtering stage (42) configured to filter the second component (S_{Q-DEM}; V_{Q-DEM+}, V_{Q-DEM-}) of the acquisition signal (S_{S}; V_{S+}, V_{S-}), generating a filtered signal (S_{f}; V_{F+}, V_{F-}); a quantizer (43) configured to receive an update clock signal (CK_{FS}) having the update frequency (f_{FS}) and to generate a digital correction signal (N_{C}, s_{C}), from the filtered signal, having a data rate equal to the update frequency; and a modulator (45; 145) configured to generate the quadrature cancellation signal (S_{CANC}, I_{CANC}; I_{CANC+}, I_{CANC-}), modulating the amplitude and/or phase thereof as a function of the digital correction signal, so as to cancel the quadrature component (I_{Q}) of the measurement signal in the input signal (S_{M}+S_{CANC}).

The input stage (20; 120) may have an input node (17; 113, 114) configured to receive the measurement signal, the modulator may include a first variable capacitor (60; 160A, 160B) having a first terminal (61; 162) coupled to the input node of the input stage and a second terminal (62; 161) configured to receive an input voltage (V_{CANC-C}; V_{C+}, V_{C-}) that is a function of the reference signal, the digital correction signal (N_{C}) being configured to modify the capacitance of the first variable capacitor and modulate the amplitude of the quadrature cancellation signal.

The correction signal may include a sign signal (s_{C}) indicative of a phase-shift sign of the filtered signal (S_{f}), the modulator further including a phase-shift block (63; 167) configured to invert the phase of the quadrature cancellation signal (S_{CANC}, I_{CANC}; I_{CANC+}, I_{CANC-}) as a function of the sign signal.

The update clock signal (CK_{FS}) may be synchronized with the zero crossings of the reference signal (S_{R}; V_{R+}, V_{R-}).

The reference signal may have a first frequency (f_{D}) and the update frequency (f_{FS}) may be equal to double the first frequency.

The control circuit configured to receive the reference signal (S_{R}; V_{R+}, V_{R-}) from an oscillating system (3; 103) of the MEMS gyroscope, the control circuit may further include a driving module (15; 115) configured to generate a driving signal (S_{D}, V_{D+}, V_{D-}) having a first frequency (f_{D}) and configured to cause a driving oscillation of the oscillating system (3; 103), the reference signal being indicative of the driving oscillation of the oscillating system.

The driving module may be configured to generate a first demodulating signal (CK₀) having the first frequency and in quadrature with respect to the reference signal, a second demodulating signal (CK₉₀) having the first frequency and in-phase with respect to the reference signal, the processing stage (30) being configured to extract the first component of the acquisition signal using the first demodulating signal, the quadrature correction stage (37; 137) being configured to extract the second component of the acquisition signal using the second demodulating signal.

The modulator may further include a second variable capacitor (70; 170A, 170B) and a register (68), the second variable capacitor having a first terminal (71; 173) coupled to the input node (17; 113, 114) of the input stage (20; 120) and a second terminal (72; 171) configured to receive a second input voltage (V_{CANC-H}; V_{R+}, V_{R-}) that is a function of the reference signal, the register (68) being configured to generate a calibration correction signal (N_{H}, S_{H}), the calibration correction signal (N_{C}) being configured to set a calibration capacitance value of the second variable capacitor.

The input stage (120) may have a first input (113) and a second input (114) and may be configured to receive a measurement signal of differential type from the MEMS gyroscope and a quadrature cancellation signal (I_{CANC+}, I_{CANC-}) of differential type from the quadrature correction stage (137).

A MEMS gyroscope (1; 100) may be summarized as including a control circuit (4; 104) according to any of the preceding claims and an oscillating system (3; 103) configured to generate the measurement signal (S_{M}).

A control method for a MEMS gyroscope (1; 100) may be summarized as including a control circuit (4; 104), the control method comprising, by the control circuit: receiving a measurement signal (S_{M}) having a quadrature component (IQ) and a sensing component (I_{Cor}) from the MEMS gyroscope; acquiring an input signal (S_{M}+S_{CANC}), the input signal being a function of the measurement signal and of a quadrature cancellation signal (S_{CANC}, I_{CANC}; I_{CANC+}, I_{CANC-}); generating an acquisition signal (S_{S}; V_{S+}, V_{S-}) in response to the acquisition of the input signal; extracting a first component (S_{S-DEM}; V_{S-DEM}) of the acquisition signal (S_{S}; V_{S+}, V_{S-}) indicative of the sensing component of the measurement signal, the first component of the acquisition signal having a sensing frequency band; extracting a second component (S_{Q-DEM}; V_{Q-DEM+}, V_{Q-DEM-}) of the acquisition signal (S_{S}; V_{S+}, V_{S-}) indicative of the quadrature component of the measurement signal; and generating the quadrature cancellation signal (S_{CANC}, I_{CANC}; I_{CANC+}, I_{CANC-}) from a reference signal (S_{R}, V_{CANC-C}; V_{C+}, V_{C-}), wherein the quadrature cancellation signal is a signal modulated as a function of the second component of the acquisition signal, at an update frequency (f_{FS}) which is outside the sensing frequency band.

Generating the quadrature cancellation signal may include filtering the second component of the acquisition signal, generating a filtered signal (S_{f}; V_{F+}, V_{F-}); generating, from the filtered signal and by a quantizer (43) controlled by an update clock signal (CK_{FS}) having the update frequency, a digital correction signal (N_{C}, s_{C}) having a data rate equal to the update frequency; and modulating amplitude and/or phase of the quadrature cancellation signal as a function of the digital correction signal, to cancel the quadrature component (I_{Q}) of the measurement signal in the input signal (S_{M}+S_{CANC}).

The update clock signal may be synchronized with the zero crossings of the reference signal (S_{R}, V_{R+}, V_{R-}).

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A control circuit for a MEMS gyroscope, comprising:
an input stage configured to acquire an input signal and to generate an acquisition signal in response to the input signal;
a processing stage configured to obtain a first component of the acquisition signal; and
a quadrature correction stage configured to extract a second component of the acquisition signal and to generate a quadrature cancellation signal based on a reference signal, the second component of the acquisition signal being indicative of a quadrature component of a measurement signal.

2. The control circuit of claim 1, wherein the input signal is a function of the measurement signal and of the quadrature cancellation signal.

3. The control circuit of claim 1, wherein the quadrature cancellation signal is a signal modulated as a function of the second component of the acquisition signal, at an update frequency which is outside of a sensing frequency band.

4. The control circuit of claim 1, wherein the first component of the acquisition signal is indicative of a sensing component of the measurement signal and having a sensing frequency band.

5. The control circuit of claim 1, wherein the processing stage includes a demodulator, an analog-to-digital converter, and a digital processor.

6. The control circuit of claim 5, wherein the demodulator extracts the first component of the acquisition signal and the analog-to-digital converter discretizes the first component of the acquisition signal.

7. The control circuit of claim 1, wherein the quadrature correction stage includes a quadrature demodulator, a filtering stage, a quantizer, and a correction modulator.

8. The control circuit of claim 7, wherein the filtering stage includes a low-pass filter and an amplifier.

9. The control circuit of claim 8, wherein the quadrature demodulator receives the acquisition signal and outputs a demodulated quadrature signal, the low-pass filter receives the demodulation quadrature signal, and the amplifier generates a filtered signal that is received by the quantizer.

10. The control circuit of claim 9, wherein the quantizer compares a value of the filter signal with a threshold value and generates a fine capacitance signal.

11. The control circuit of claim 10, wherein the fine capacitance signal is a numerical value of a ratio between the filtered signal and a conversion reference signal, wherein the conversion reference signal equals the threshold value.

12. The control circuit of claim 10, wherein the correction modulator includes a first variable capacitor, a first phase shifter, an attenuator, a register, a second variable capacitor, and a second phase shifter.

13. The control circuit of claim 12, wherein a first capacitance of the first variable capacitor is controlled by the fine capacitance signal and a second capacitance of the second variable capacitor is controlled by a coarse capacitance signal.

14. A method, comprising:
receiving a measurement signal from a MEMS gyroscope;
generating an acquisition signal as a function of the measurement signal
extracting a first component of the acquisition signal having a sensing frequency band;
extracting a second component of the acquisition signal; and
generating a quadrature cancellation signal that is modulated based on the second component of the acquisition signal.

15. The method of claim 14, wherein the measurement signal has a quadrature component and a sensing component, the first component of the acquisition signal being indicative of the sensing component of the measurement signal and the second component of the acquisition signal being indicative of the quadrature component of the measurement signal.

16. The method of claim 14, comprising acquiring an input signal, the input signal being a function of the measurement signal and of the quadrature cancellation signal, wherein the generating the acquisition signal is in response to the acquiring the input signal.

17. The method of claim 14, wherein the quadrature cancellation signal is modulated based on the second component of the acquisition signal at an update frequency which is outside the sensing frequency band.

18. A device comprising:
an oscillating system; and
a control circuit, the control circuit including:
a driving module;
a sensing circuit coupled to an output of the oscillating system;
a signal processing module; and
a correction module including a quadrature demodulator, a filtering stage, a quantizer, and a correction module.

19. The device of claim 18, wherein the oscillating system includes a movable structure, a driving structure, and a sensing structure that includes a sensing capacitor, and the sensing circuit an amplifier coupled to the sensing structure and a feedback capacitor.

20. The device of claim 19, wherein the signal processing module includes a demodulator, an analog-to-digital converter, and a digital processor, the signal processing module being configured to obtain a first component of an acquisition signal, and wherein the correction module is configured to extract a second component of the acquisition signal and to generate a quadrature cancellation signal based on a reference signal, the second component of the acquisition signal being indicative of a quadrature component of a measurement signal.
